(19) United States
(12) Patent Application Publication
(10) Pub. No.: US 2025/0176136 A1
(43) Pub. Date: May 29, 2025

(54) DISTRIBUTION DEVICE FOR A THERMAL MANAGEMENT SYSTEM

(71) Applicant: VALEO SYSTEMES THERMIQUES, La Verriere (FR)

(72) Inventor: Dominik SPORNA, San Mateo, CA (US)

(73) Assignee: VALEO SYSTEMES THERMIQUES, La Verriere (FR)

(21) Appl. No.: 18/519,910

(22) Filed: Nov. 27, 2023

(51) Int. Cl. H05K 7/20; H01M 10/613; H01M 10/6564; H01M 50/383

(52) U.S. Cl. CPC H05K 7/20281; H01M 10/613; H01M 10/6564; H01M 50/383; H05K 7/20263; H05K 7/20272

(57) ABSTRACT

A distribution device for a thermal management system, including a component configured to handle a heat exchange fluid and an extinguisher valve connected fluidically with the component so that the heat exchange fluid can flow therebetween. The distribution device is adapted to operate with CO2 as the heat exchange fluid. The extinguisher valve is configured to selectively release the heat exchange fluid into ambient.

### TECHNICAL FIELD

This disclosure thermal management systems, for example in the automotive field.

### BACKGROUND OF THE INVENTION

The development of electric vehicles has brought new issues to the automotive field, in particular in view of the limited autonomy of the electric battery as well as the limited space that can be dedicated to the thermal management system at the bottom of the vehicle system because of the positioning of the electric battery at the front of the vehicle. For these reasons, compact thermal management systems and more and more desired.

Evolution of vehicle architecture also leads to new challenges in terms of fire risk, as some components like electronic units or battery packs generate significant amount of heat. In some cases, the materials used to manufacture such components are flammable and pose an increased risk for passengers.

### SUMMARY OF THE INVENTION

An object of the invention is, among others, a distribution device for a thermal management system, comprising: a component configured to handle a heat exchange fluid, an extinguisher valve connected fluidically with the component so that the heat exchange fluid can flow therebetween; wherein the distribution device is adapted to operate with CO2 as the heat exchange fluid, wherein the extinguisher valve is configured to selectively release the heat exchange fluid into ambient.

In one example, the extinguisher valve is configured to release the heat exchange fluid into ambient in a specific direction.

In one example, the distribution device further comprises a device inlet and a device outlet for the heat exchange fluid, wherein the extinguisher valve is arranged downstream of the component.

In one example, the distribution device further comprises a device inlet and a device outlet for the heat exchange fluid, wherein the extinguisher valve is arranged upstream of the component.

In one example, the component includes an accumulator for the heat exchange fluid.

In one example, the component includes a plate heat exchanger.

In one example, the extinguisher valve includes a housing with a housing inlet configured to receive the heat exchange fluid, and an extinguisher outlet for egressing the heat exchange fluid into the ambient.

In one example, the extinguisher valve is of rotary type.

In one example, the extinguisher valve is of rectilinear type.

In one example, the extinguisher outlet is configured to direct the egressed heat exchange fluid away from the distribution device.

In one example, the housing includes a housing outlet with an outlet fluid line configured to convey the heat exchange fluid downstream the distribution device.

In one example, the extinguisher valve includes a diverter configured to assume a first position in which the diverter prevents flow between the housing inlet and the extinguisher outlet.

In one example, the extinguisher valve includes a diverter configured to assume a second position in which the diverter enables flow between the housing inlet and the extinguisher outlet.

In one example, the housing includes a housing outlet with an outlet fluid line configured to convey the heat exchange fluid downstream the distribution device, wherein the extinguisher valve includes a diverter configured to assume a third position in which diverter enables flow between the housing inlet and the housing outlet, and prevents flow between the housing inlet and the extinguisher outlet.

In one example, the housing includes a housing outlet with an outlet fluid line configured to convey the heat exchange fluid downstream the distribution device, wherein the extinguisher valve includes a diverter configured to assume fourth position in which the diverter partly enables flow between the housing inlet and the housing outlet, and prevents flow between the housing inlet and the extinguisher outlet, so that the heat exchange fluid can be expanded while passing through the housing outlet.

In one example, the housing includes a housing outlet with an outlet fluid line configured to convey the heat exchange fluid downstream the distribution device, wherein in the first position the diverter prevents flow between the extinguisher outlet and the housing outlet.

In one example, the housing includes a housing outlet with an outlet fluid line configured to convey the heat exchange fluid downstream the distribution device, wherein in the second position the diverter prevents flow between the housing inlet and the housing outlet.

Another object of the invention is a thermal management system comprising: a distribution device with: a component configured to handle a heat exchange fluid, an extinguisher valve connected fluidically with the component so that the heat exchange fluid can flow therebetween; wherein the distribution device is adapted to operate with CO2 as the heat exchange fluid, wherein the extinguisher valve is configured to selectively release the heat exchange fluid into ambient; thermal management system further comprising a heat source, wherein the extinguisher valve is configured to release the heat exchange fluid in the direction of the heat source so that heat exchange fluid reaches the heat source.

In one example, the heat source is an electronic device.

In one example, the heat source is a battery pack.

### BRIEF DESCRIPTION OF DRAWINGS

The present invention will be described in greater detail below with reference to the drawings. In the drawings:

FIG. 1 shows a diagram of a thermal management system;

FIG. 2 shows a diagram of a thermal management system with an example of a distribution device;

FIG. 3 shows a diagram of a thermal management system with another example of a distribution device;

FIG. 4 shows an example of a distribution device and a heat source;

FIG. 5 shows an example of an extinguisher valve in a first position;

FIG. 6 shows the extinguisher valve of FIG. 5 in a second position;

FIG. 7 shows another example of an extinguisher valve in a first position;

FIG. 8 shows the extinguisher valve of FIG. 7 in a second position;

FIG. 9 shows the extinguisher valve of FIG. 7 in a third position;

FIG. 10 shows the extinguisher valve of FIG. 7 in a fourth position;

FIG. 11 shows another example of an extinguisher valve in a first position;

FIG. 12 shows the extinguisher valve of FIG. 11 in a second position;

FIG. 13 shows the extinguisher valve of FIG. 11 in a third position;

FIG. 14 shows the extinguisher valve of FIG. 11 in a fourth position; and

FIG. 15 shows another example of a distribution device.

### DETAILED DESCRIPTION OF THE INVENTION

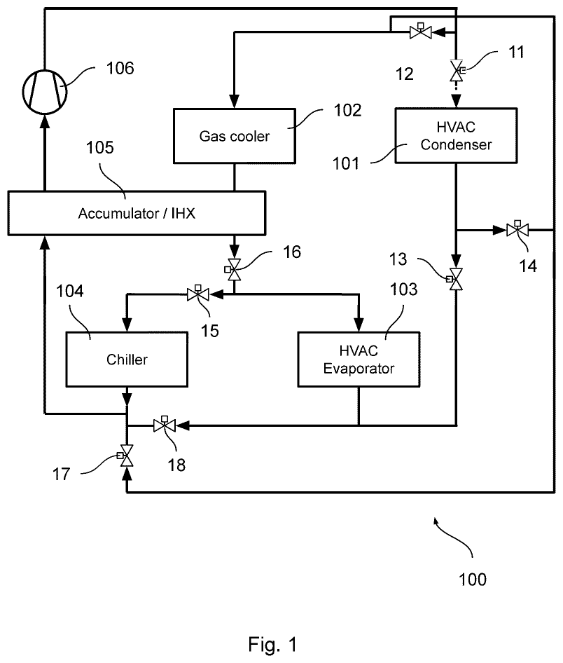

FIG. 1 shows a diagram of a thermal management system 100. The thermal management system 100 can include a heat ventilation and air conditioning system (HVAC) condenser 101, an gas cooler 102, an HVAC evaporator 103, a chiller 104, an accumulator/IHX (Internal Heat Exchanger) 105, and a compressor 106.

The thermal management system 100 can include a valve block 10, for example with eight valves, in particular a first valve 11, a second valve 12, a third valve 13, a fourth valve 14, a fifth 15, a sixth valve 16, a seventh valve 17 and an eighth valve 18.

The first valve 11 ensures the management of the refrigerant fluid into the HVAC condenser 101, and is arranged to be connected to the compressor 106. The second valve 12 ensures the management of the refrigerant fluid into the gas cooler 104, and is connected to the compressor 106. The third valve 13 is arranged between an exit of the HVAC condenser 101 and the eighth valve 18. The fourth valve 14 is arranged between the exit of the HVAC condenser 101 and the seventh valve 17. The fifth valve 15 ensures the management of the refrigerant fluid into the chiller 104, and is arranged between the sixth valve 16 and the chiller 104. The sixth valve 16 is arranged between an exit of the accumulator/IHX 105 and the fifth valve 15. The seventh valve 17 is arranged between the fourth valve 14 and the accumulator/IHX 105, and the eighth valve 18 is arranged between the third valve 13 and the accumulator/IHX 105.

Preferably, all the valves 11-18 can open and close in two directions. At least valves 14, 15 and 16, and preferably all the valves 11-18, can expand in both directions.

The functioning of the thermal management system 100 is described below according to different modes.

In a cabin cooling mode, the arrangement of the valves 11-18 is the following: the first valve 11 is closed, the second valve 12 is open, the third valve 13 is closed, the fourth valve 14 is closed, the fifth valve 15 is closed, the sixth valve 16 is the expansion valve, the seventh valve 17 is closed, and the eighth valve 18 is open.

In this mode, the compressor 106 ensures the circulation of the refrigerant fluid (in a high pressure, high temperature, gaseous state) through the second valve 12 to the gas cooler 102. There, the refrigerant fluid cools down. The fluid then flows to the sixth valve 16 working as an expansion valve, where it is regulated to flow at a proper rate before penetrating the HVAC evaporator 103 where it evaporates and returns to the compressor 106 through the eighth valve 18 and the accumulator/IHX 105. The air of the cabin is cooled down thanks to the thermal exchanges with the refrigerant fluid in the HVAC evaporator 103.

In a battery cooling mode, the arrangement of the valves 11-18 is the following: the first valve 11 is closed, the second valve 12 is open, the third valve 13 is closed, the fourth valve 14 is closed, the fifth valve 15 is the expansion valve, the sixth valve 16 is open, the seventh valve 17 is closed, and the eighth valve 18 is closed.

In this mode, the compressor 106 ensures the circulation of the refrigerant fluid (in a high pressure, high temperature, gaseous state) through the second valve 12 to the gas cooler 102. There, the refrigerant fluid cools down. The fluid then flows to the fifth valve 15, working as an expansion valve, through the sixth valve 16. In the fifth valve 15, the fluid is regulated to flow at a proper rate before penetrating the chiller 104 where it evaporates and returns to the compressor 106 through the accumulator/IHX 105 while the eighth valve 18 is closed. The battery is cooled down by a coolant that is cooled down thanks to the thermal exchanges with the refrigerant fluid in the chiller 104.

In a heat pump mode, where the cabin is heated with the ambient heat, the arrangement of the valves 11-18 is the following: the first valve 11 is open, the second valve 12 is closed, the third valve 13 is closed, the fourth valve 14 is the expansion valve, the fifth valve 15 is closed, the sixth valve 16 is open, the seventh valve 17 is closed, and the eighth valve 18 is open.

In this mode, the compressor 106 ensures the circulation of the refrigerant fluid (in a high pressure, high temperature, gaseous state) through the first valve 11 to the HVAC condenser 101. In the HVAC condenser 101, the cabin air is heated while the refrigerant fluid cools down. The fluid then flows to the fourth valve, working as an expansion valve, wherein the fluid is regulated to flow at a proper rate before penetrating the gas cooler 102. In the gas cooler 102, the refrigerant fluid heats up and returns to the compressor 106 through the sixth valve 16, the HVAC evaporator 103, the eighth valve 18 and the accumulator/IHX 105. The HVAC evaporator 103 ensures the dehumidification of the air flowing through the HVAC condenser 101.

In another heat pump mode, where the cabin is heated with the ambient heat and further provides heat recovery, the arrangement of the valves 11-18 is the following: the first valve 11 is open, the second valve 12 is closed, the third valve 13 is closed, the fourth valve 14 is an expansion valve, the fifth valve 15 is an expansion valve, the sixth valve 16 is open, the seventh valve 17 is closed, and the eighth valve 18 is open.

In this mode, the compressor 106 ensures the circulation of the refrigerant fluid (in a high pressure, high temperature, gaseous state) through the first valve 11 to the HVAC condenser 101. In the HVAC condenser 101, the cabin air is heated while the refrigerant fluid cools down. The fluid then flows to the fourth valve 14, working as an expansion valve, wherein the fluid is regulated to flow at a proper rate before penetrating the gas cooler 102. In the gas cooler 102, the refrigerant fluid heats up and returns to the compressor 106 through two distinct circuits: in a first circuit, the fluid flows through the sixth valve 16, the HVAC evaporator 103 for dehumidification, the eighth valve 18 and the accumulator/IHX 105, and, in a second circuit, the fluid flows through the fifth valve 15 and the chiller 104. In the chiller 104, the refrigerant recovers heat from the coolant which has been heated up by, for example, the electrical motor of the vehicle (further heat recovery inside through the chiller 104).

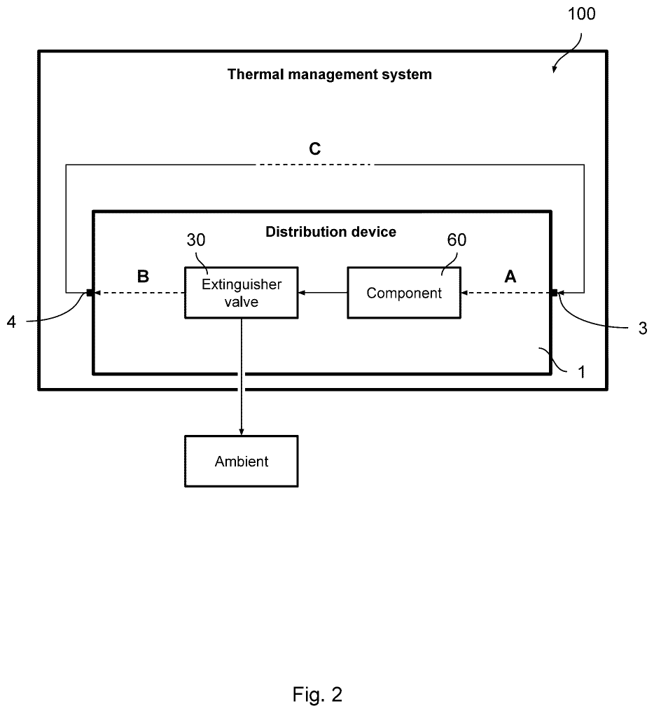

FIG. 2 shows a diagram of a thermal management system 100 with an example of a distribution device 1. The distribution device 1 includes a component 60 configured to handle a heat exchange fluid.

The component 60 can be (or in other words—can include) a heat exchanger, in particular a plate heat exchanger like a chiller or a liquid condenser, an air-to-liquid heat exchanger like a radiator, an air heater, a fluid manifold, a valve block 10, an accumulator, a reservoir, an internal heat exchanger.

The distribution device 1 includes an extinguisher valve 30 connected fluidically with the component 60 so that the heat exchange fluid can flow therebetween. In one example, the heat exchange fluid can be arranged to flow from the component 60 to the extinguisher valve 30. In another example, the extinguisher valve 30 can be pass-through element from which the heat exchange fluid is allowed to travel towards the component 60 when the extinguisher valve 30 is not releasing the heat exchange fluid into the ambient.

The distribution device 1 is adapted to operate with CO2 (carbon dioxide, otherwise known as R744) as the heat exchange fluid. This heat exchange fluid is non-flammable and is stored under high pressure. While being egressed from its enclosure, it displaces oxygen on its path. Upon release, CO2 also has a very low temperature, so it is able to at least partially cool the heat source. For these reasons, it is very well suited for the purpose of extinguishing, or at least temporary minimizing/decreasing, a heat source that caught on fire.

The extinguisher valve 30 is configured to selectively release the heat exchange fluid into ambient. In other words, the extinguisher valve 30 can be selected to block release of the heat exchange fluid into the ambient or to allow release the heat exchange fluid into the ambient. The extinguisher valve 30 can be configured to release the heat exchange fluid into ambient in a specific direction. In particular, the heat exchange fluid may be released towards and onto a heat source 20 that is overheating or that has already started burning.

The distribution device 1 can further include a device inlet 3 and a device outlet 4 for the heat exchange fluid. The device inlet 3 is then located upstream of the component 60 and the extinguisher valve 30, while the device outlet 4 is located downstream of the component 60 and the extinguisher valve 30.

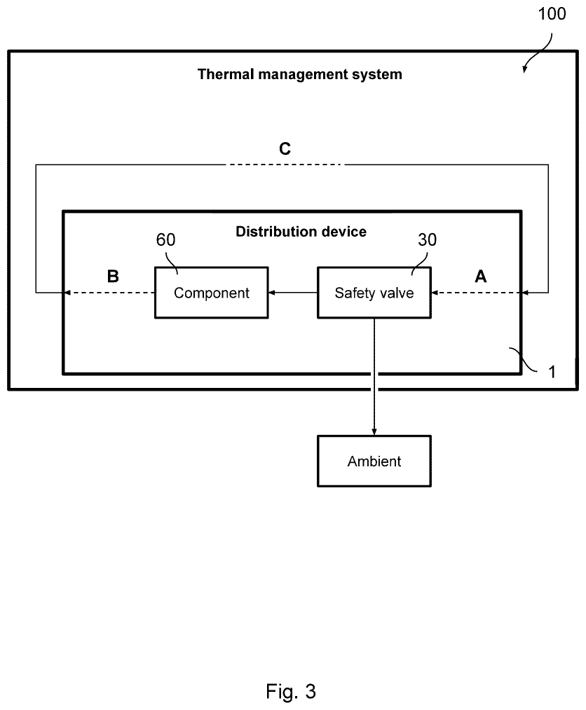

As shown in FIG. 2, the extinguisher valve 30 can be arranged downstream of the component 60. Conversely, as shown in FIG. 3, the extinguisher valve 30 can be arranged upstream of the component 60.

The distribution device 1 can include an upstream section A, arranged between the device inlet 3 and the extinguisher valve 30 with the component 60. The upstream section A can include a plate heat exchanger, e.g. a chiller 104, an accumulator/IHX 105, a compressor 106, fluid handling elements, such sensors, inlets, outlets, as well as channels for the guiding of the heat exchange fluid between the inlets, outlets, sensors.

The distribution device 1 can include a downstream section B, arranged between the device outlet 4 and the extinguisher valve 30 with the component 60. The downstream section B can include a plate heat exchanger, e.g. a chiller 104, an accumulator/IHX 105, a compressor 106, fluid handling elements, such sensors, inlets, outlets, as well as channels for the guiding of the heat exchange fluid between the inlets, outlets, sensors.

The valve block 10 can be part of the upstream section A. The valve block 10 can be part of the upstream section B. The valve block 10 can be functionally shared between the upstream section A and downstream section B, with some of the valves 11-18 handling fluid travelling through the elements of the upstream section A and some of the valves 11-18 handling fluid travelling through the elements of the downstream section B.

The thermal management system 100 can include an external section C, arranged functionally between the device outlet 4 and the device inlet 3. The external section C can include elements of the thermal management system not already included in the distribution device 1. These elements can include, for example, the HVAC condenser 101, the gas cooler 102, the HVAC evaporator 103, the chiller 104, the accumulator/IHX 105, the compressor 106.

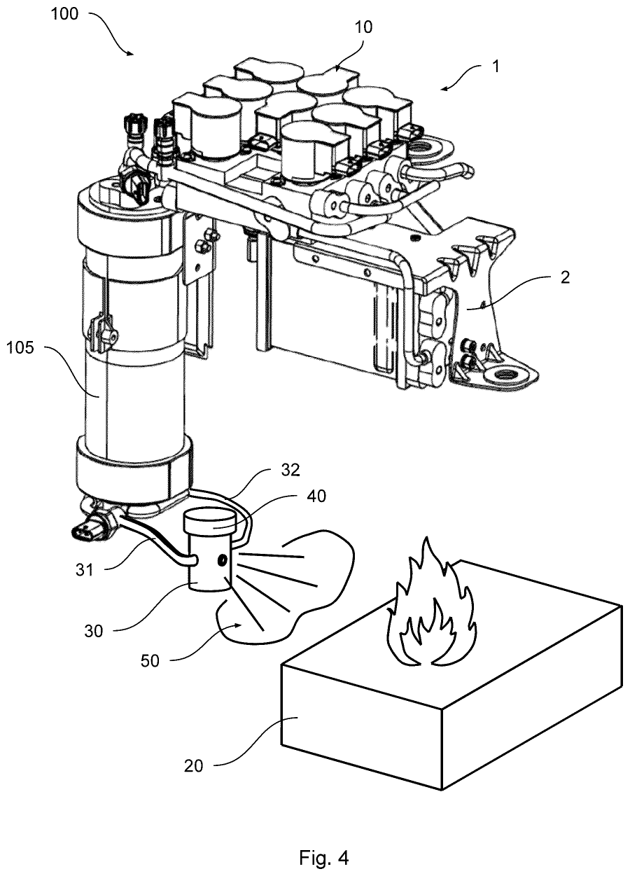

FIG. 4 shows an example of a distribution device 1 and a heat source 20. The distribution device 1 can include a bracket 2 serving as a mounting portion for other elements, including those handling the heat exchange fluid.

The extinguisher valve 30 is configured to release the heat exchange fluid in the direction of the heat source 20 so that heat exchange fluid reaches the heat source 20. The heat source 20 can be an electronic device, for example a domain controller, an ECU, an ADAS computing unit or similar. The heat source 20 can also be a battery pack.

The extinguisher valve 30 can be powered by an actuator 40. The extinguisher valve 30 can be fluidically connected to the component 60 by an inlet fluid line 31. In one example, the extinguisher valve 30 can also be connected to the component 60 and/or to the downstream section B of the distribution device 1 by an outlet fluid line 32.

The design of the extinguisher valve 30 can be adjusted to operate at the right pressure and mass flow rate to provide maximum neutralization capability. These parameters can for example be tuned based on the type of the heat source 20 with which the extinguisher valve 30 is foreseen to cooperate.

As can be seen in FIG. 4, the extinguisher valve 30 can direct a stream 50 of the heat exchange fluid (CO2) from the distribution device 1 towards the heat source 20. If the heat source 20 is burning, the stream 50 can extinguish the fire or at least decrease the intensity thereof so that the passenger can gain additional time to escape the vehicle into safety. Additionally or alternatively, there is a higher chance to save/transmit more data relating to the thermal incident prompting a reaction of the extinguisher valve 30, which can help further analysis and evaluation of the root cause of the incident.

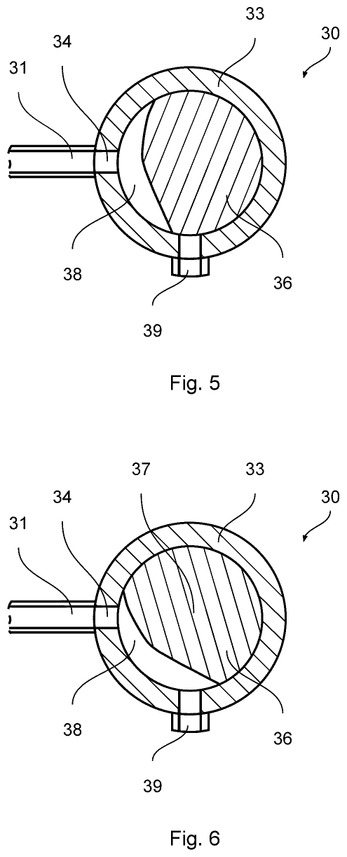

FIG. 5 shows an example of an extinguisher valve 30. The extinguisher valve 30 can be of rotary type. The extinguisher valve 30 can include a housing 33 with a housing inlet 34 configured to receive the heat exchange fluid, and an extinguisher outlet 39 for egressing the heat exchange fluid into the ambient. The extinguisher outlet 39 can be configured to direct the egressed heat exchange fluid away from the distribution device 1. The extinguisher outlet 39 can include a nozzle.

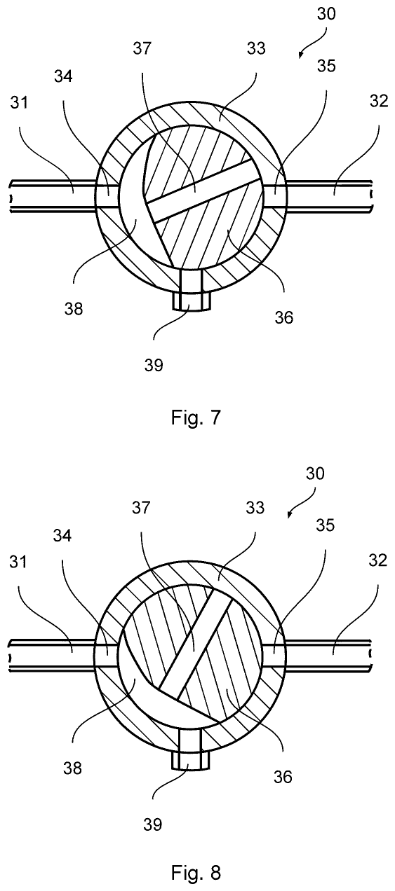

In FIG. 5, there is shown an example of an extinguisher valve 30 in a first position. In particular, the extinguisher valve 30 can include a diverter 36. In the shown example, the diverter 36 is specifically shaped so as to rotate within the housing 33. The diverter 36 is shaped to create a free volume 38 within the housing which can be filled with CO2 from the housing inlet 34 and which can be communicated, by appropriately positioning the diverter 36, with the extinguisher outlet 39, or as shown in FIGS. 7-10, with a housing outlet 35. The diverter 36 can be configured to assume a first position in which the diverter 36 prevents flow between the housing inlet 34 and the extinguisher outlet 39.

FIG. 6 shows the extinguisher valve 30 of FIG. 5 in a second position. The diverter 36 can be configured to assume a second position in which the diverter 36 (at least partly, preferably fully) enables flow between the housing inlet 34 and the extinguisher outlet 39.

FIG. 7 shows another example of an extinguisher valve 30. The housing 33 can include a housing outlet 35 with an outlet fluid line 32 configured to convey the heat exchange fluid downstream the distribution device 1. In its first position, the diverter 36 can prevent flow between the extinguisher outlet 39 and the housing outlet 35. The diverter 36 can include a distribution channel 37 to connect the free volume 38 with selected portions of the housing 33, for example with the housing outlet 35.

FIG. 8 shows the extinguisher valve 30 of FIG. 7 in a second position, in which the diverter 36 can prevent flow between the housing inlet 34 and the housing outlet 35.

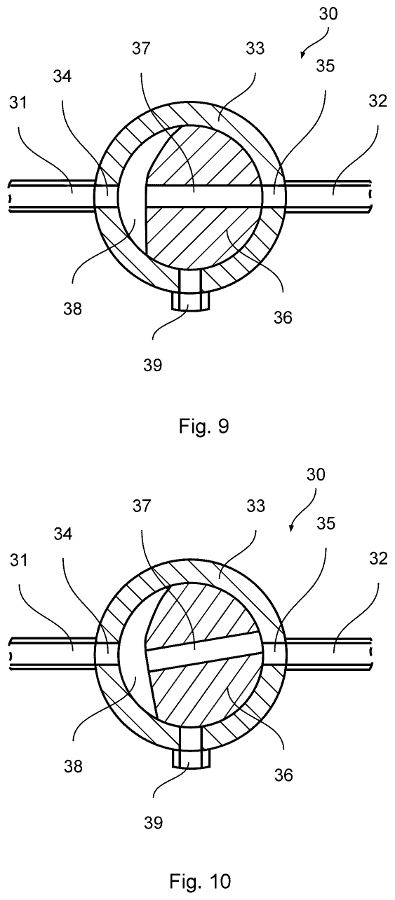

FIG. 9 shows the extinguisher valve 30 of FIG. 7 in a third position. In particular, the diverter 36 can be configured to assume a third position in which diverter 36 enables flow between the housing inlet 34 and the housing outlet 35, and prevents flow between the housing inlet 34 and the extinguisher outlet 39. As shown, the diverter 36 also prevents flow between the housing outlet 35 and the extinguisher outlet 39.

FIG. 10 shows the extinguisher valve 30 of FIG. 7 in a fourth position. In particular, the diverter 36 can be configured to assume fourth position in which the diverter 36 partly enables flow between the housing inlet 34 and the housing outlet 35, and prevents flow between the housing inlet 34 and the extinguisher outlet 39, so that the heat exchange fluid can be expanded while passing through the housing outlet 35. As shown, the diverter 36 also prevents flow between the housing outlet 35 and the extinguisher outlet 39.

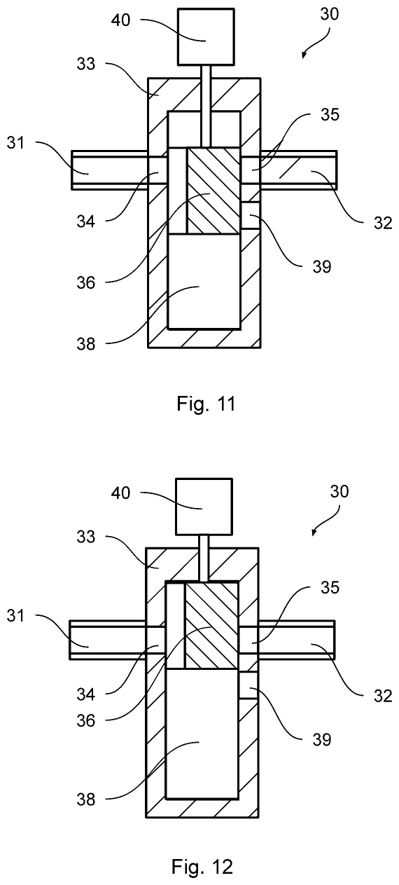

FIG. 11 shows another example of an extinguisher valve 30 in a first position. The extinguisher valve 30 can include the housing 33 with the housing inlet 34 configured to receive the heat exchange fluid, and the extinguisher outlet 39 for egressing the heat exchange fluid into the ambient. The extinguisher outlet 39 can be configured to direct the egressed heat exchange fluid away from the distribution device 1. The extinguisher outlet 39 can include a nozzle. The extinguisher valve 30 can include the diverter 36. In the shown example, the diverter 36 is specifically shaped so as to move linearly within the housing 33. The diverter 36 is shaped to create a free volume 38 within the housing which can be filled with CO2 from the housing inlet 34 and which can be communicated, by appropriately positioning the diverter 36, with the extinguisher outlet 39 or with the housing outlet 35. The diverter 36 can be configured to assume a first position in which the diverter 36 prevents flow between the housing inlet 34 and the extinguisher outlet 39. The housing 33 can include the housing outlet 35 with an outlet fluid line 32 configured to convey the heat exchange fluid downstream the distribution device 1. In its first position, the diverter 36 can prevent flow between the extinguisher outlet 39 and the housing outlet 35.

As shown in FIGS. 11-14, the extinguisher valve 30 can be of rectilinear type. The diverter 36 can be actuated by the actuator 40.

FIG. 12 shows the extinguisher valve 30 of FIG. 11 in a second position. The diverter 36 can be configured to assume a second position in which the diverter 36 (at least partly, preferably fully) enables flow between the housing inlet 34 and the extinguisher outlet 39. In the second position, the diverter 36 can prevent flow between the housing inlet 34 and the housing outlet 35.

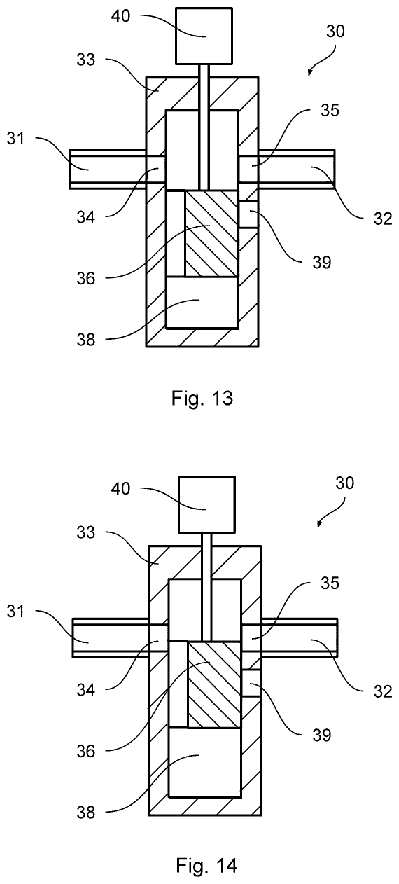

FIG. 13 shows the extinguisher valve 30 of FIG. 11 in a third position. In particular, the diverter 36 can be configured to assume a third position in which diverter 36 enables flow between the housing inlet 34 and the housing outlet 35, and prevents flow between the housing inlet 34 and the extinguisher outlet 39. As shown, the diverter 36 also prevents flow between the housing outlet 35 and the extinguisher outlet 39.

FIG. 14 shows the extinguisher valve 30 of FIG. 11 in a fourth position. In particular, the diverter 36 can be configured to assume fourth position in which the diverter 36 partly enables flow between the housing inlet 34 and the housing outlet 35, and prevents flow between the housing inlet 34 and the extinguisher outlet 39, so that the heat exchange fluid can be expanded while passing through the housing outlet 35. As shown, the diverter 36 also prevents flow between the housing outlet 35 and the extinguisher outlet 39.

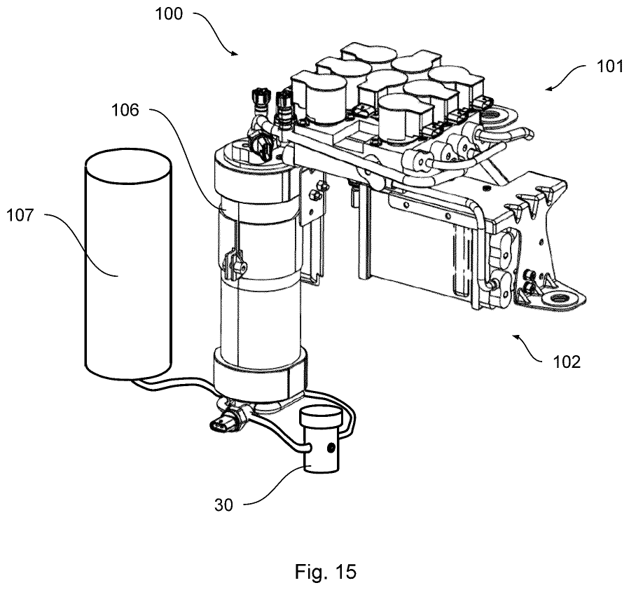

FIG. 15 shows another example of a distribution device 1. In general, the thermal management system 100 can contain about 500 grams of CO2 under high pressure. In one example, the distribution device 1 can include a reservoir 107 to enlarge the total volume of CO2 available. This reservoir 107 can be activated for example only in case of safety hazard and thermal runway or thermal incident. In one example, the reservoir 107 is not used during the regular operation (e.g. heating or cooling cycle) so as not to impact the system efficiency. In one example, the reservoir 107 is designed to hold another 500 g of CO2 in addition to the amount already led within the thermal management system 100, which will lengthen the time the stream 50 of CO2 is supplied to the heat source 20 or increase the amount of CO2 that is supplied. The reservoir 107 can be replaceable and/or rechargeable, for example in regular time intervals, for example during vehicle's service. The reservoir 107 can be situated in a convenient spot within vehicle, so that it can be easily accessible for service.

The invention claimed is:

1. A distribution device for a thermal management system, comprising:
a component configured to handle a heat exchange fluid,
an extinguisher valve connected fluidically with the component so that the heat exchange fluid can flow therebetween;
wherein the distribution device is adapted to operate with CO2 as the heat exchange fluid,
wherein the extinguisher valve is configured to selectively release the heat exchange fluid into ambient.

2. The distribution device according to claim 1, wherein the extinguisher valve is configured to release the heat exchange fluid into ambient in a specific direction.

3. The distribution device according to claim 1, further comprising a device inlet and a device outlet for the heat exchange fluid, wherein the extinguisher valve is arranged downstream of the component.

4. The distribution device according to claim 1, further comprising a device inlet and a device outlet for the heat exchange fluid, wherein the extinguisher valve is arranged upstream of the component.

5. The distribution device according to claim 1, wherein the component includes an accumulator for the heat exchange fluid.

6. The distribution device according to claim 1, wherein the component includes a plate heat exchanger.

7. The distribution device according to claim 1, wherein the extinguisher valve includes a housing with a housing inlet configured to receive the heat exchange fluid, and an extinguisher outlet for egressing the heat exchange fluid into the ambient.

8. The distribution device according to claim 1, wherein the extinguisher valve is of rotary type.

9. The distribution device according to claim 1, wherein the extinguisher valve is of rectilinear type.

10. The distribution device according to claim 7, wherein the extinguisher outlet is configured to direct the egressed heat exchange fluid away from the distribution device.

11. The distribution device according to claim 7, wherein the housing includes a housing outlet with an outlet fluid line configured to convey the heat exchange fluid downstream the distribution device.

12. The distribution device according to claim 7, wherein the extinguisher valve includes a diverter configured to assume a first position in which the diverter prevents flow between the housing inlet and the extinguisher outlet.

13. The distribution device according to claim 7, wherein the extinguisher valve includes a diverter configured to assume a second position in which the diverter enables flow between the housing inlet and the extinguisher outlet.

14. The distribution device according to claim 7, wherein the housing includes a housing outlet with an outlet fluid line configured to convey the heat exchange fluid downstream the distribution device, wherein the extinguisher valve includes a diverter configured to assume a third position in which diverter enables flow between the housing inlet and the housing outlet, and prevents flow between the housing inlet and the extinguisher outlet.

15. The distribution device according to claim 7, wherein the housing includes a housing outlet with an outlet fluid line configured to convey the heat exchange fluid downstream the distribution device, wherein the extinguisher valve includes a diverter configured to assume fourth position in which the diverter partly enables flow between the housing inlet and the housing outlet, and prevents flow between the housing inlet and the extinguisher outlet, so that the heat exchange fluid can be expanded while passing through the housing outlet.

16. The distribution device according to claim 12, wherein the housing includes a housing outlet with an outlet fluid line configured to convey the heat exchange fluid downstream the distribution device, wherein in the first position the diverter prevents flow between the extinguisher outlet and the housing outlet.

17. The distribution device according to claim 13, wherein the housing includes a housing outlet with an outlet fluid line configured to convey the heat exchange fluid downstream the distribution device, wherein in the second position the diverter prevents flow between the housing inlet and the housing outlet.

18. A thermal management system comprising:
a distribution device with:
a component configured to handle a heat exchange fluid,
an extinguisher valve connected fluidically with the component so that the heat exchange fluid can flow therebetween;
wherein the distribution device is adapted to operate with CO2 as the heat exchange fluid,
wherein the extinguisher valve is configured to selectively release the heat exchange fluid into
ambient;
a heat source,
wherein the extinguisher valve is configured to release the heat exchange fluid in the direction of the heat source so that heat exchange fluid reaches the heat source.

19. The thermal management system according to claim 18, wherein the heat source is an electronic device.

20. The thermal management system according to claim 18, wherein the heat source is a battery pack.
